(19) United States
(12) Patent Application Publication
(10) Pub. No.: US 2015/0311921 A1
(43) Pub. Date: Oct. 29, 2015

(54) MEMORY CONTROLLER, STORAGE DEVICE AND DECODING METHOD

(71) Applicant: Kabushiki Kaisha Toshiba, Minato-ku (JP)

(72) Inventors: Juan SHI, Yokohama (JP); Osamu TORII, Setagaya (JP); Naoaki KOKUBUN, Yokohama (JP)

(73) Assignee: Kabushiki Kaisha Toshiba, Minato-ku (JP)

(21) Appl. No.: 14/479,724

(22) Filed: Sep. 8, 2014

Related U.S. Application Data
(60) Provisional application No. 61/984,136, filed on Apr. 25, 2014.

(51) Int. Cl. H03M 13/29; G06F 11/10

(52) U.S. Cl. CPC H03M 13/2909; G06F 11/1076

(57) ABSTRACT

According to one embodiment, a memory controller includes a first decoder that decodes a block product code read out from a non-volatile memory and calculates reliability information of each sub-block, and an error cancellation unit that detects a sub-block having many errors based on the reliability information, and performs EXOR operation of a codeword in a column direction including the detected sub-block and a codeword in a row direction including the detected sub-block, and performs decoding using a result of the EXOR operation.

### CROSS-REFERENCE TO RELATED APPLICATIONS

This application is based upon and claims the benefit of priority from U.S. Provisional Application No. 61/984,136, filed on Apr. 25, 2014; the entire contents of which are incorporated herein by reference.

### FIELD

Embodiments described herein relate generally to a memory controller, a storage device, and a decoding method.

### BACKGROUND

A phenomenon that, when user data stored in a memory is read out from the memory, the user data is changed from an original value into a different value, or when data transmitted by a transmitting device is received by a receiving device, the received data is changed from an original value into a different value may be caused. To deal with such a problem, a method of performing error correction encoding of the user data is typically used.

As one of error correction codes, there is a block product code. The block product code defines a sub-block configured from user data of a plurality of bits or a plurality of symbols. The sub-block is a configuration element of both of a codeword in a vertical direction and a codeword in a horizontal direction. The block product code iterates decoding of a codeword in the vertical direction and decoding of a codeword in the horizontal direction to correct an error of the user data.

### BRIEF DESCRIPTION OF THE DRAWINGS

FIG. 1 is a block diagram illustrating a configuration example of a storage device according to an embodiment;

FIG. 2 is a diagram illustrating an example in which a sub-block including many errors exists in a block product code;

FIG. 3 is a diagram illustrating a configuration example of a block product code;

FIG. 4 is a diagram illustrating an order of generation of a block product code;

FIG. 5 is a diagram illustrating an example of sub-blocks that configure codewords in a horizontal direction and in a vertical direction;

FIG. 6 is a diagram illustrating an example of arrangement orders of bits in the horizontal direction and in the vertical direction;

FIG. 7 is a diagram illustrating a configuration example of a decoder of an embodiment;

FIG. 8 is a flowchart illustrating an example of a procedure of decoding processing of an embodiment;

FIG. 9 is a flowchart illustrating an example of a processing procedure of error cancellation of an embodiment;

FIG. 10 is a flowchart illustrating an example of a processing procedure of error cancellation of S_{t,t};

FIG. 11 is a diagram schematically illustrating error cancellation of S_{t,t};

FIG. 12 is a flowchart illustrating an example of a processing procedure of error cancellation of S_{t,v}; and

FIG. 13 is a diagram schematically illustrating error cancellation of S_{t,v}.

### DETAILED DESCRIPTION

In general, according to one embodiment, a memory controller includes a first decoder that controls a non-volatile memory storing a block product code in which codewords including a plurality of sub-blocks are arranged in a column direction and in a row direction, and decodes the block product code read out from the non-volatile memory to calculate reliability information of each sub-block. The memory controller includes an error cancellation unit that detects a sub-block having many errors based on the reliability information, and performs an EXOR operation of the codeword in the column direction including the detected sub-block and the codeword in the row direction including the detected sub-block, and performs decoding using a result of the EXOR operation.

A memory controller, a storage device, and a decoding method according to embodiments will be described in detail with reference to the appended drawings. Note that the present invention is not limited by these embodiments.

### Embodiments

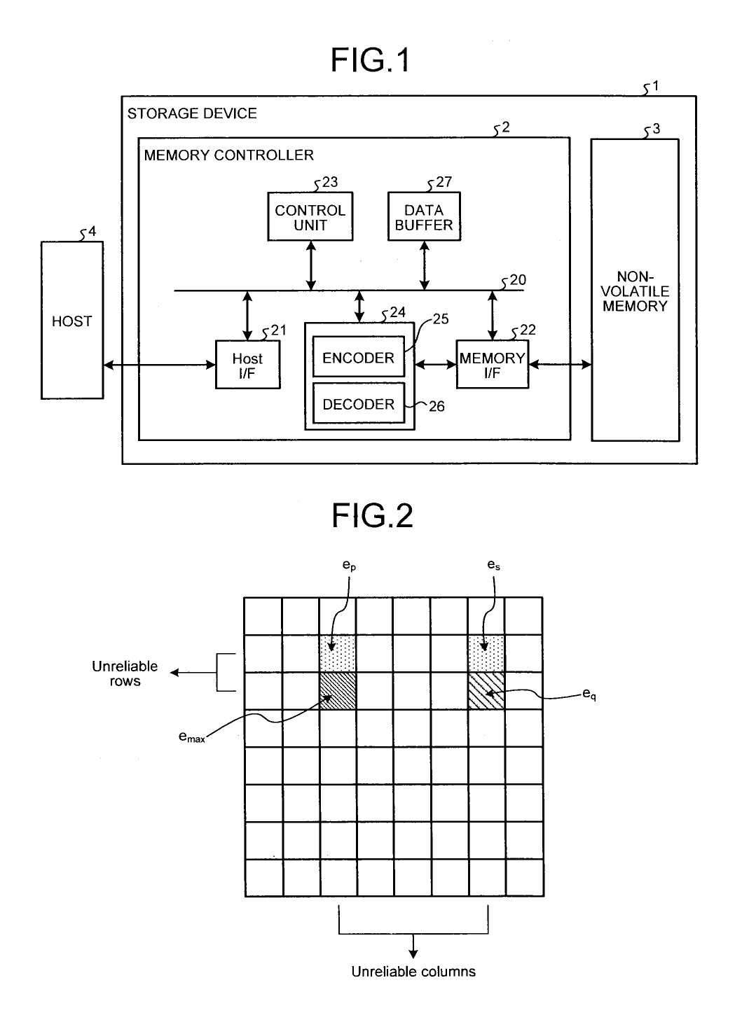

FIG. 1 is a block diagram illustrating a configuration example of a storage device according to an embodiment. A storage device 1 of the present embodiment includes a memory controller 2 and a non-volatile memory 3. The storage device 1 is connectable with a host 4, and FIG. 1 illustrates a state in which the storage device 1 is connected with the host 4. The host 4 is an electronic device, such as a personal computer, or a mobile terminal.

The non-volatile memory 3 is a non-volatile memory that stores data in a non-volatile manner, and is a NAND memory, for example. Note that, here an example of using a NAND memory as the non-volatile memory 3 will be described. However, the non-volatile memory 3 may be a memory other than a NAND memory. The NAND memory performs writing and reading out of data for each write unit data typically called page.

The memory controller 2 controls writing to the non-volatile memory 3 according to a write command from the host 4. Further, the memory controller 2 controls readout from the non-volatile memory 3 according to a readout command from the host 4. The memory controller 2 includes a Host I/F 21, a memory I/F 22, a control unit 23, an encoder/decoder 24, and a data buffer 27, and these units are mutually connected by an internal bus 20.

The Host I/F 21 outputs a command received from the host 4, user data (write data), and the like to the internal bus 20. Further, the Host I/F 21 transmits the user data read out from the non-volatile memory 3, a response from the control unit 23, and the like to the host 4.

The memory I/F 22 controls write processing and readout processing of the user data, and the like to/from the non-volatile memory 3 based on an instruction of the control unit 23.

The control unit 23 comprehensively controls the storage device 1. The control unit 23 is a central processing unit (CPU), a micro processing unit (MPU), or the like. When having received a command from the host 4 through the Host I/F 21, the control unit 23 performs control according to the command. For example, the control unit 23 instructs the memory I/F 22 to perform writing of the user data and parity to the non-volatile memory 3 according to the command from the host 4. Further, the control unit 23 instructs the memory I/F 22 to perform readout of the user data and parity from the non-volatile memory 3 according to the command from the host 4.

The control unit 23 determines a storage area (memory area) on the non-volatile memory 3 with respect to the user data. The control unit 23 performs the determination of a memory area with respect to data (page data) of a page unit that is a write unit. As described below, in the present embodiment, the user data is encoded and stored in the non-volatile memory 3 as a codeword. Therefore, the page data includes at least the codeword. In the present specification, memory cells connected to the same word line are defined as a memory cell group. When the memory cells are multi-level cells, the memory cell group corresponds to a plurality of pages. For example, when multi-level cells capable of storing two bits are used, the memory cell group corresponds to two pages. The control unit 23 determines the memory area of the non-volatile memory 3 of a write-destination for each page data. In the memory area of the non-volatile memory 3, a physical address is allocated. The control unit 23 manages the memory area of the write-destination of the page data using the physical address. The control unit 23 designates the determined memory area (physical address) and instructs the memory I/F 22 to write the user data in the non-volatile memory 3. The control unit 23 manages correspondence between a logical address (a logical address managed by the host 4) and the physical address of the user data. When having received a readout command including the logical address from the host 4, the control unit 23 identifies the physical address corresponding to the logical address, designates the physical address, and instructs the memory I/F 22 to perform readout of the user data.

The data buffer 27 temporarily stores the user data received from the host 4 until storing the user data in the non-volatile memory 3, and temporarily stores the data read out from the non-volatile memory 3 until transmitting the data to the host 4. The data buffer 27 is configured from a general-purpose memory, such as a static random access memory (SRAM) or a dynamic random access memory (DRAM).

The encoder/decoder 24 includes an encoder 25 and a decoder 26. The encoder 25 encodes the user data to generate codewords. As described below, the encoder 25 performs encoding using the block product code. The decoder 26 decodes the codeword read out from the non-volatile memory 3. Details of the encoding and the decoding in the present embodiment will be described below.

In FIG. 1, a configuration example in which the memory controller 2 separately includes the encoder/decoder 24 and the memory I/F 22 has been described. However, the encoder/decoder 24 may be built in the memory I/F 22.

Here, the block product code will be described. The block product code is a type of product code, and is an extended standard product code. In a product code, information to be protected (user data) is protected by codewords in two directions: a codeword in the horizontal direction and a codeword in the vertical direction. The codeword in the horizontal direction in the product code is called horizontal component code and the codeword in the vertical direction is called vertical component code. An area (bit line) where one horizontal component code and one vertical component code intersect with each other is a sub-block. In other words, one horizontal component code and one vertical component code intersect with each other in sub-block units. The product code realizes high error correction capability by iterating decoding in the horizontal direction and decoding in the vertical direction.

The sub-block is configured from a plurality of bits in a case of a Bose, Chandhuri, Hocquenghem (BCH) code, and is configured from a plurality of symbols in a case of a Reed-Solomon (RS) code. In the block product code, a codeword in the horizontal direction and a codeword in the vertical direction intersect with each other in sub-block units.

In the block product code, there is a case in which errors cannot be corrected even if decoding in the horizontal direction and decoding in the vertical direction are iterated if there are many errors in a specific sub-block. FIG. 2 is a diagram illustrating an example in which a sub-block including many errors exists in the block product code. In FIG. 2, each rectangle indicates a sub-block. The rectangles with hatching indicate sub-blocks including errors. A codeword configured from the sub-blocks including errors includes errors. In FIG. 2, each row is a codeword in the horizontal direction, and each column is a codeword in the vertical direction. In FIG. 2, the codewords in the horizontal direction including errors are indicated by Unreliable rows, and the codewords in the vertical direction including errors are indicated by Unreliable columns. Among the sub-blocks including errors, the number of errors of a sub-block having a maximum number of errors is eₘₐₓ. Other than the above sub-block, sub-blocks having the number of errors of eₚ, e_{q}, and eₛ exist, and eₚ, e_{q}, and eₛ are smaller than eₘₐₓ. Here, for simplification of the description, a case in which the number of errors (eₚ, e_{q}, eₛ, or the like) of each sub-block is calculated as the reliability information in the decoding of the block product code will be described. However, the reliability information may be any information as long as the information is a value that indicates probability of a sub-block depending on the number of errors.

For example, the error correction capability t₁ (the number of correctable errors) of a codeword in the horizontal direction is 5, and the error correction capability (the number of correctable errors) t₂ of a codeword in the vertical direction is 4. Further, eₘₐₓ is 4, eₚ is 3, eₛ is 3, and e_{q} is 2. The codeword in the horizontal direction including the sub-block having the number of errors of eₘₐₓ also includes the sub-block having the number of errors of e_{q}, and thus includes six errors as a total. The codeword in the vertical direction including the sub-block having the number of errors of eₘₐₓ also includes the sub-block having the number of errors of eₚ, and thus includes seven errors as a total. Therefore, the decoder fails in correction of the errors of these codewords. If the decoder succeeds in the error correction of a codeword in the horizontal direction including the sub-block having the number of errors of eₚ but not including the sub-block having the number of errors of eₘₐₓ, the decoder succeeds in the error correction of the codeword in the vertical direction including the sub-block having the number of errors of eₘₐₓ using the codeword in the vertical direction after correction of eₚ. However, the codeword in the horizontal direction including the sub-block having the number of errors of eₚ but not including the sub-block having the number of errors of eₘₐₓ also includes the sub-block having the number of errors of eₛ. Therefore, the decoder fails in the error correction of the codeword. Further, the codeword in the vertical direction including the sub-block having the number of errors of eₛ also includes the sub-block having the number of errors of e_{q}. Therefore, the decoder fails in the error correction of the codeword. Therefore, the errors of these Unreliable rows and Unreliable columns cannot be corrected even if decoding is iterated in the horizontal direction and the vertical direction.

Meanwhile, if the errors of the sub-block having the number of errors of eₘₐₓ can be removed, the number of errors of the Unreliable rows and the Unreliable columns can be decreased. As described above, by removal of errors of one or more sub-blocks including errors, a possibility of correcting the errors is increased. The present embodiment improves the error correction capability by removing the errors of the sub-block including errors by error cancellation described below.

Hereinafter, encoding and decoding of the present embodiment will be described. First, encoding for performing error cancellation, that is, generation of the block product code will be described. As described above, in the present embodiment, the user data is encoded using the block product code. As an error correction code used in the encoding to generate codewords in the horizontal direction and in the vertical direction, any code can be used as long as the code is a cyclic linear code. For example, a BCH code, an RS code, a part of a low density parity check (LDPC) code (an LDPC code that satisfies a condition of the cyclic linear code), or the like can be used. Note that the codeword in the horizontal direction and the codeword in the vertical direction are generated using the same error correction code. Further, a Galois field of the codeword in the horizontal direction and a Galois field of the codeword in the vertical direction are equal. Note that the error cancellation of the present embodiment can be applied to a case where sizes of effective information (user data) in the horizontal direction and in the vertical direction are different if a code length in the horizontal direction and a code length in the vertical direction are made equal by performing of 0 padding.

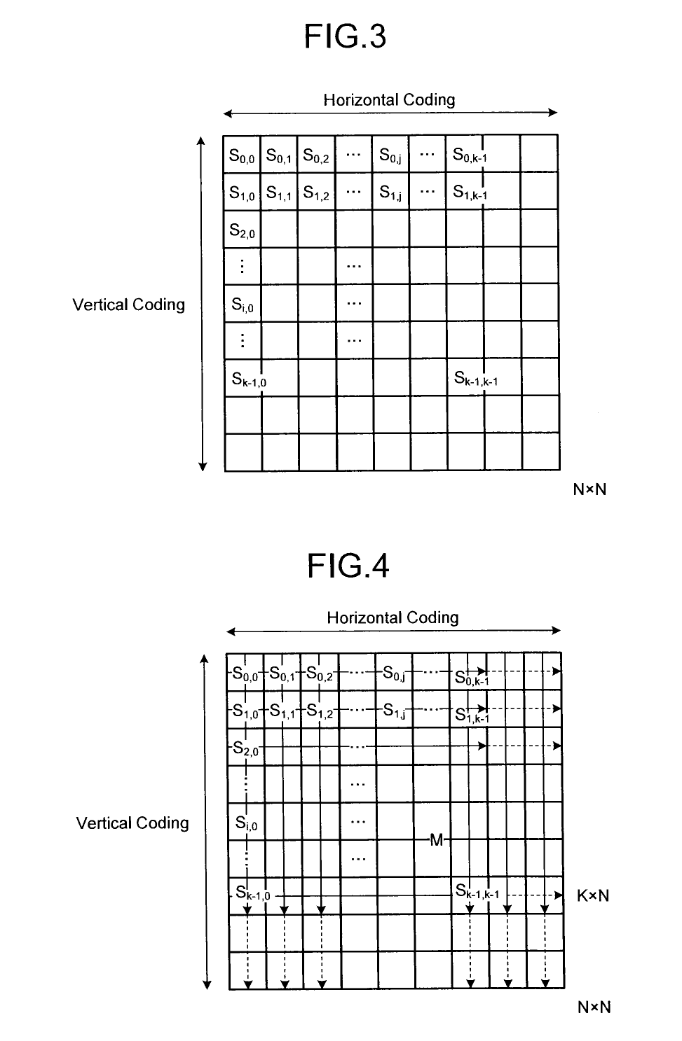

In the block product code, the codeword in the horizontal direction and the codeword in the vertical direction intersect with each other in sub-block units, as described above. FIG. 3 is a diagram illustrating a configuration example of the block product code. As illustrated in FIG. 3, a sub-block is written as S_{i,j}. i indicates an order in the vertical direction, and j indicates an order in the horizontal direction.

FIG. 4 is a diagram illustrating an order of generation of the block product code. The generation of the block product code is started from the horizontal coding. Each codeword has an information part (S_{i,0}, S_{i,1}, . . . , S_{i,K-1}) having the length of K. A parity part can be obtained by encoding of the information part by a code C₁. The whole of the codeword is (S_{i,0}, S_{i,1}, . . . , S_{i,N-1}) εC₁. Here, i=0, 1, . . . , K—1. C₁ indicates an error correction code in the horizontal direction. By performing of the processing with respect to all of rows, the rows of a matrix M are encoded by the code C₁, and a K×N matrix is generated. Following that, to obtain an N×N matrix, columns of the K×N matrix are encoded in the vertical direction by a code C₂. C₂ indicates an error correction code in the vertical direction. In the encoding of columns where i is K or more, parity of the parity part of the codeword in the horizontal direction is generated.

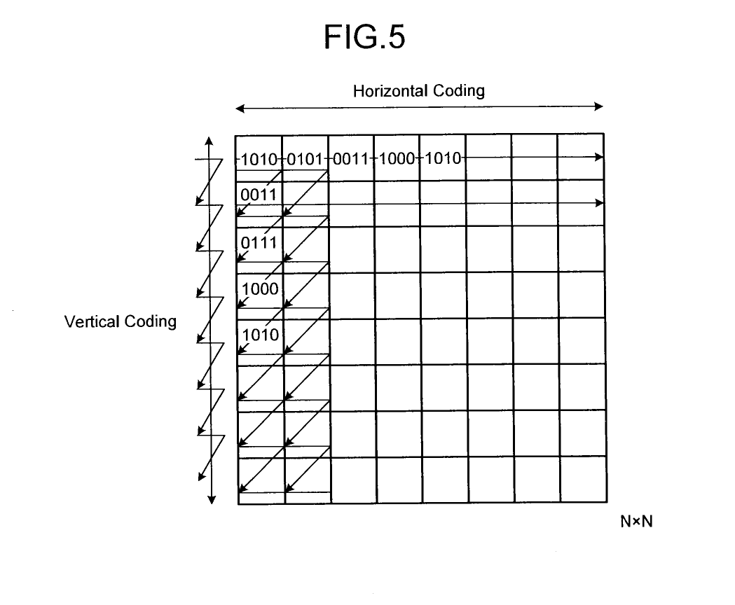

FIG. 5 is a diagram illustrating an example of sub-blocks that configure codewords in the horizontal direction and in the vertical direction. FIG. 5 illustrates an example in which a sub-block is configured from four bits. Each rectangle of FIG. 5 indicates one sub-block. Among the sub-blocks, a numerical value “1010”, and the like are numerical value examples of the four bits that configure a sub-block. Note that FIG. 5 is one example, and the number of bits that configures a sub-block is not limited to the example. When a sub-block is configured from four bits, the information part in the horizontal direction illustrated in FIG. 4 is 4×K bits, and a code length n is 4×N bits. A code length in the vertical direction is also 4×N bits.

The arrangement order of the bits in the horizontal coding is similar to a case of a standard product code. Meanwhile, regarding the arrangement order of the bits in the vertical coding, the bit order in the sub-block S_{i,j} is the same as the horizontal direction, and the order is (S_{0,j}, S_{1,j}, . . . , S_{K-1,j}) regarding all of js, as illustrated in FIG. 5.

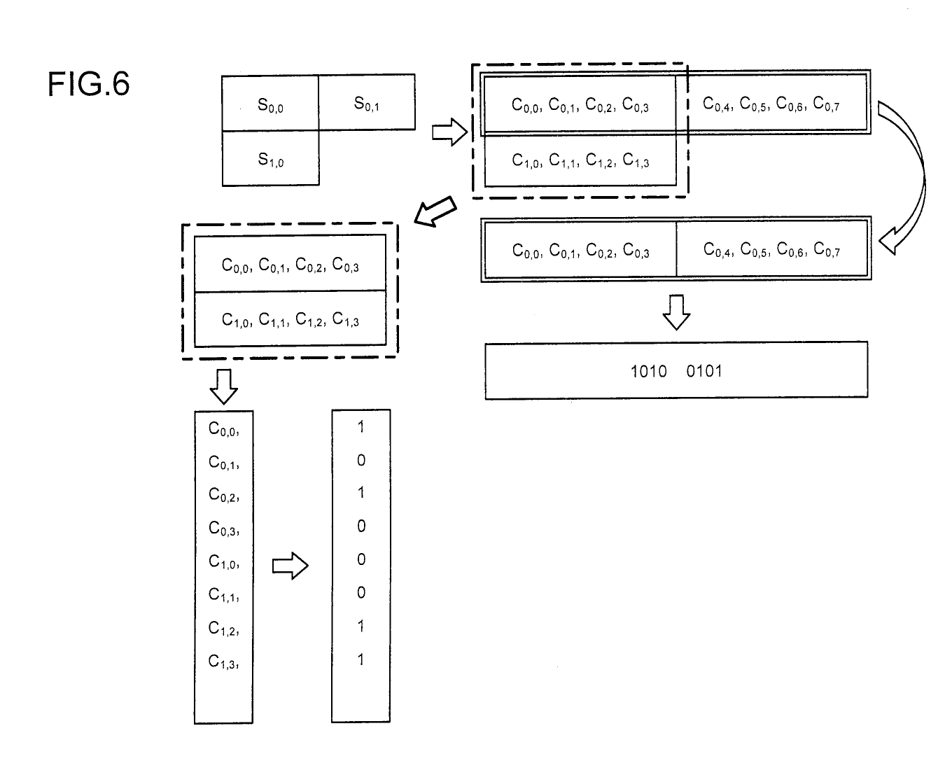

FIG. 6 is a diagram illustrating an example of arrangement orders of bits in the horizontal direction and in the vertical direction. FIG. 6 illustrates, as illustrated in FIG. 5, parts of the codewords in the horizontal direction and in the vertical direction where four bits that configure S_{0,0} are “1010”, four bits that configure S_{0,1} are “0011”, and four bits that configure S_{1,0} are “0101”. Codewords expressed by (S_{i,0}, S_{i,1}, . . . , S_{i,N-1}) in bit units are c=(c_{i,0}, c_{i,1}, . . . , c_{i,n-1}). The codewords (c_{i,0}, c_{i,1}, . . . , c_{i,n-1}) are codewords of a code C. That is, (c_{i,0}, c_{i,1}, . . . , c_{i,n-1}) εC. S_{0,0} is (c_{0,0}, c_{0,1}, c_{0,2}, c_{0,3}) and S_{0,1} is (c_{0,4}, c_{0,5}, c_{0,6}, c_{0,7}). Therefore, a codeword in the horizontal direction includes (c_{0,0}, c_{0,1}, c_{0,2}, c_{0,3}, c_{0,4}, c_{0,5}, c_{0,6}, c_{0,7})=“10100101”. Further, a codeword in the vertical direction includes (c_{0,0}, c_{0,1}, c_{0,2}, c_{0,3}, c_{1,0}, c_{1,1}, c_{1,2}, and c_{0,3}). Therefore, the information part of the codeword in the column direction where j=0 is (c_{0,0}, c_{0,1}, c_{0,2}, c_{0,3}, c_{1,0}, c_{1,1}, c_{1,2}, c_{0,3} . . . , c_{k-1,0}, c_{k-1,1}, c_{k-1,2}, c_{k-1,3}).

Therefore, the encoding takes a zigzag route in terms of bit units, as illustrated in FIG. 5. By performing of such encoding, properties of linear code can be used.

Note that, after the generation of the N×N matrix illustrated in FIGS. 3 and 4, the sub-blocks are stored in the non-volatile memory 3. There is no particular limitation to a storage format of the non-volatile memory 3. For example, one codeword in the horizontal direction may be stored in one page and the N×N matrix may be stored in seven pages total, or all of the N×N matrix may be stored in one page. One codeword in the horizontal direction may be stored in a plurality of pages, and for example, one codeword in the horizontal direction may be stored in two pages and the N×N matrix may be stored in fourteen pages total.

Here, c′=(c′₀, c′₁, . . . , c′ₙ₋₁), and c and c′ are separate codewords belonging to the linear code C, the following expression (1) is established from the properties of linear code. + indicates EXOR.

c+c′=(c₀+c₁+c′₁, . . . , cₙ₋₁+c′ₙ₋₁)εC (1)

When the two linear codes of c and c′ are added, the two linear codes becomes a different codeword that belongs to the code C.

Further, when C is a cyclic linear code, a codeword shifted to the right or to the left becomes a different codeword of the code C. The following expression (2) is established where c⁽¹⁾ is a codeword obtained by shifting c to the right by one bit.

c=(c₀, c₁, . . . , c₁₋₂, cₙ₋₁)εC [symbol] c⁽¹⁾=(cₙ₋₁, c₀, c₁, . . . , cₙ₋₂)εC (2)

As illustrated in the following expression (3), c^{(w)} obtained by shifting c by w bits is also a different codeword of the code C.

c=(c₀, c₁, . . . , cₙ₋₂, cₙ₋₁)εC [symbol] c^{(w)}=(c_{n-w}, . . . , cₙ₋₁, c₀, c₁, . . . , c_{n-(w+1)})εC (3)

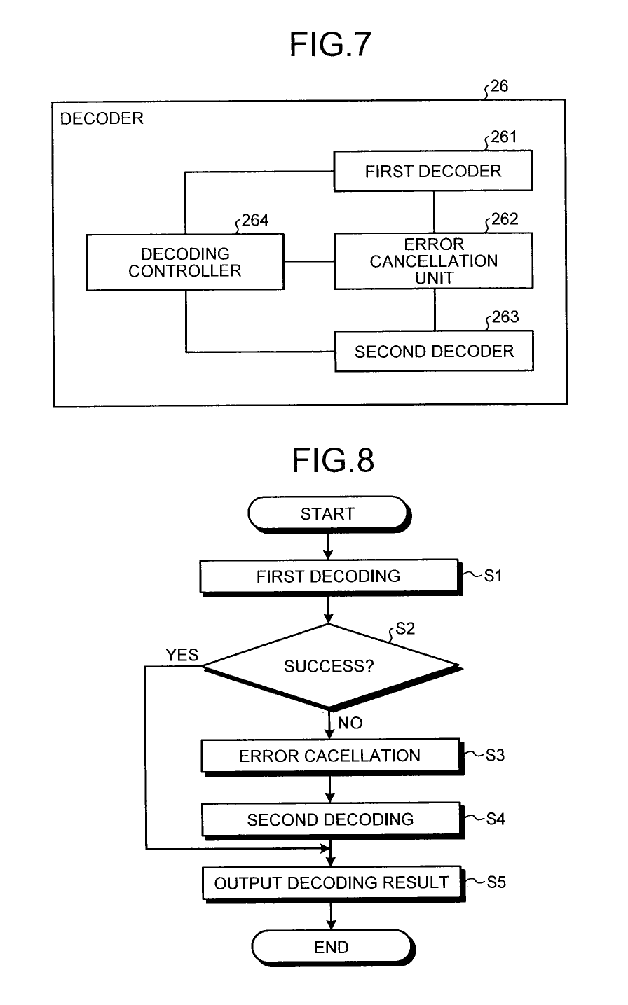

Next, decoding of the block product code of the present embodiment will be described. In the present embodiment, in the process of decoding, error cancellation is performed. FIG. 7 is a diagram illustrating a configuration example of the decoder 26 of the present embodiment. As illustrated in FIG. 7, the decoder 26 of the present embodiment includes a first decoder 261, an error cancellation unit 262, a second decoder 263, and a decoding controller 264. FIG. 7 is an example, and the configuration of the decoder 26 is not limited to the example of FIG. 7.

The first decoder 261 performs first decoding with respect to the block product code read out from the non-volatile memory 3. As a method of the first decoding, any decoding method may be used as long as the decoding method can output the reliability information of each sub-block. For example, a maximum likelihood detection (MLD) decoding method, such as a bounded distance (BD) decoding method, can be used. Hereinafter, for simplification of the description, a case in which the number of errors of each sub-block is output from the first decoder 261 as the reliability information will be described. However, the reliability information output from the first decoder 261 may be any information as long as the information is a value that indicates probability of a sub-block depending on the number of errors.

When the error correction has been failed by the first decoder 261, the error cancellation unit 262 performs error cancellation of a sub-block having a large error using the reliability information output from the first decoder 261.

The second decoder 263 performs second encoding with respect to the block product code after being subjected to the error cancellation by the error cancellation unit 262. As a second decoding method, any decoding method may be used. The second decoding method may not be a decoding method that outputs the reliability information. The second decoding method may be the same method as the first decoding. For example, a generalized minimum distance (GMD) decoding method or a BD decoding method can be used.

FIG. 8 is a flowchart illustrating a procedure of decoding processing of the present embodiment. First, the first decoder 261 performs the first decoding with respect to the block product code read out from the non-volatile memory 3 (step S1). The decoding controller 264 determines whether the first decoding has been succeeded (whether an error in the block product code has been able to be corrected) (step S2), and if succeeded (Yes in step S2), the decoding controller 264 outputs a decoding result (user data after error correction) (step S5).

When the first decoding has been failed (No in step S2), the decoding controller 264 controls the error cancellation unit 262 to performs the error cancellation, and the error cancellation unit 262 performs the error cancellation (step S3). The decoding controller 264 instructs the second decoder 263 to decode the block product code after being subjected to the error cancellation, and the second decoder 263 performs decoding (step S4). Then, the processing proceeds to step S5, and the decoding controller 264 outputs a decoding result of the second decoder 263 (user data after error correction) (step S5).

The procedure illustrated in FIG. 8 is an example, and after the error cancellation of step S3, the processing may be returned to step S1, and the first decoding may be performed again with respect to the block product code after the error cancellation instead of the second decoding. As described above, a predetermined number of times of the error cancellation and the first decoding are performed, and when the error correction is not succeeded during the processing, the second decoding may be performed. Further, when the error correction is failed by the second decoding, the processing is returned to step S1, and the processing of step S1 and subsequent processing may be iterated. Further, the second decoding is not performed, and only iteration of the error cancellation and the first decoding is performed without the second decoding. In this case, the decoder 26 may not include the second decoder 263. That is, various variations can be considered in the processing of performing the error cancellation after the first decoding and subsequent processing, and any processing can be applied to the processing of the error cancellation and subsequent processing.

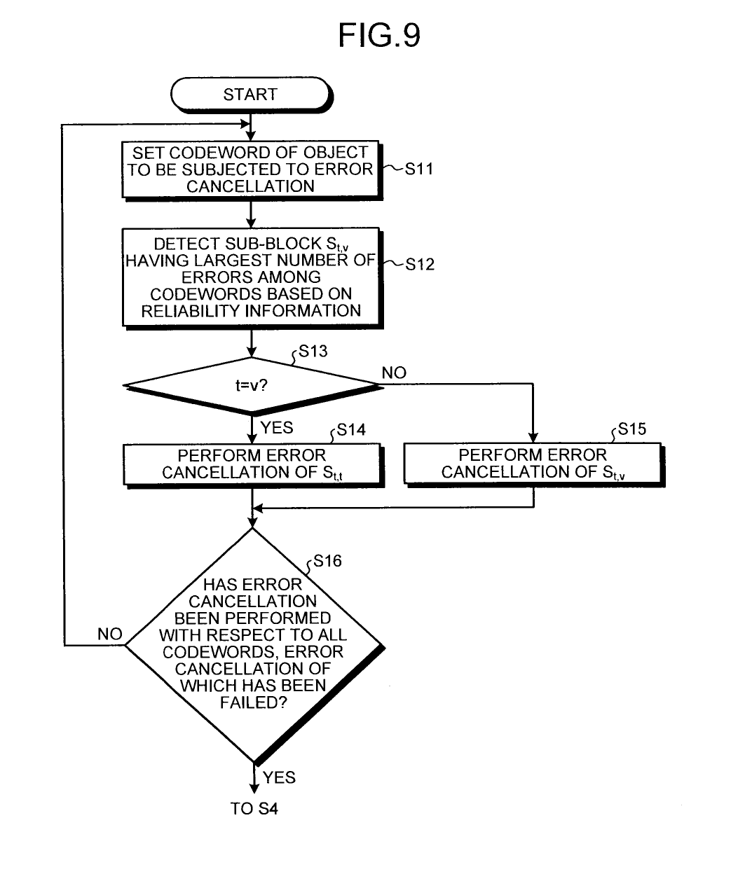

Next, the error cancellation of the present embodiment will be described. FIG. 9 is a flowchart illustrating an example of a processing procedure of the error cancellation of the present embodiment. First, the error cancellation unit 262 extracts codewords including errors based on the reliability information obtained by the first decoding. Then, the error cancellation unit 262 sets one of the extracted codewords as an object to be subjected to the error cancellation (step S11). The error cancellation unit 262 detects S_{t,v} that is a sub-block having the largest number of errors from among the codewords set as the objects to be subjected to the error cancellation based on the reliability information (step S12). The error cancellation unit 262 determines whether the detected sub-block S_{t,v} satisfies t=v (step S13). That is, the error cancellation unit 262 determines whether the detected sub-block S_{t,v} is a (diagonal) sub-block of a diagonal element in the block product code.

When having determined that t=v is satisfied (Yes in step S13), the error cancellation unit 262 performs error cancellation of S_{t,t} described below (step S14). When having determined that t=v is not satisfied (No in step S13), the error cancellation unit 262 performs error cancellation of S_{t,v} (t≠v) described below (step S15). After step S14 and step S15, the error cancellation unit 262 determines whether having performed the error cancellation with respect to all of the extracted codewords including errors (step S16). When having performed the error cancellation with respect to the extracted codewords including errors (Yes in step S16), the error cancellation unit 262 terminates the error cancellation. When there is a codeword that is not the object to be subjected to the error cancellation among the extracted codewords including errors (No in step S16), the error cancellation unit 262 changes the codeword to be the object to be subjected to the error cancellation, and returns to step S11. Note that, here, the error cancellation has been performed with respect to all of the codewords including errors. However, only a codeword including a sub-block having the maximum number of errors of the block product code may be subjected to the error cancellation. Further, only a codeword including a sub-block having a fixed number of errors may be subjected to the error cancellation.

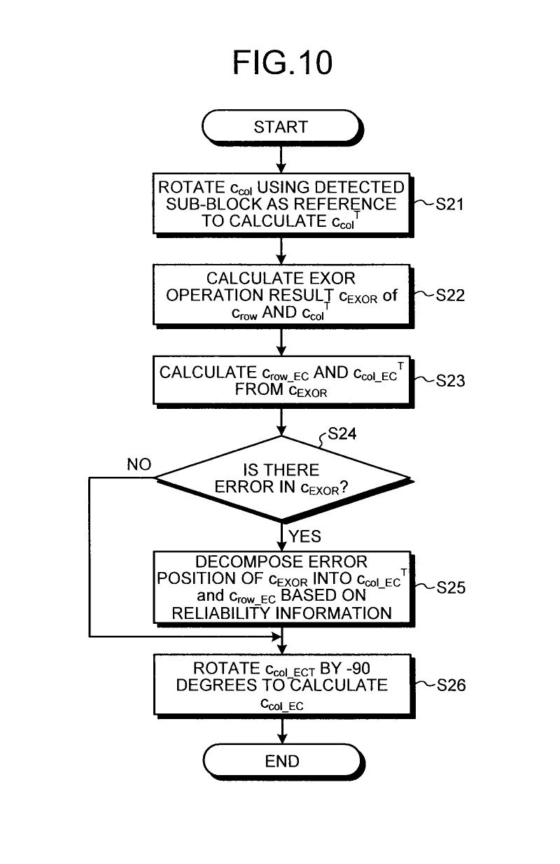

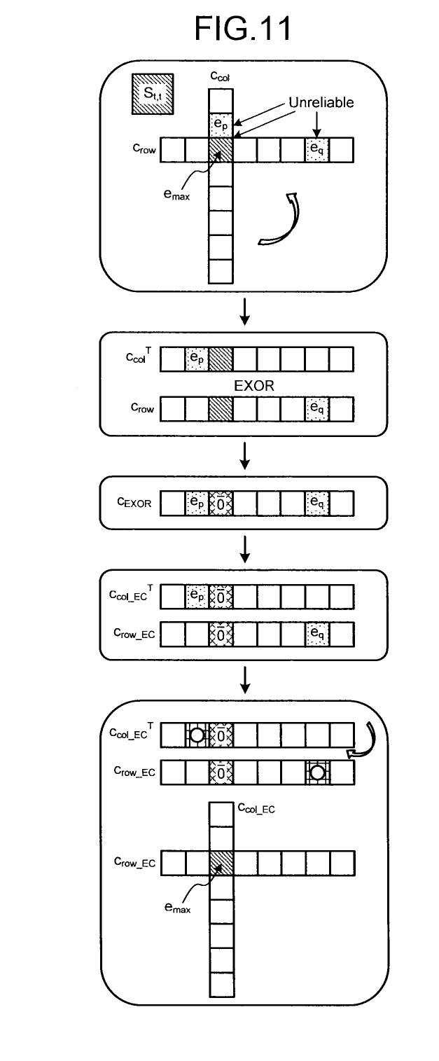

FIG. 10 is a flowchart illustrating an example of a processing procedure of error cancellation of S_{t,t}. FIG. 11 is a diagram schematically illustrating the error cancellation of S_{t,t}. The error cancellation of S_{t,t} will be described with reference to FIGS. 10 and 11. As illustrated in the diagram of the first stage of FIG. 11, the number of errors of the sub-block S_{t,t} having the largest number of errors is eₘₐₓ. A codeword in the row direction including the sub-block S_{t,t} is c_{row}, and a codeword in the column direction including the sub-block S_{t,t} is c_{col}. Further, the codeword c_{row} includes a (Unreliable) sub-block having low reliability, which has been determined to include the number of errors e_{q} based on the reliability information of the first decoding. The codeword c_{col} includes an (Unreliable) sub-block having low reliability, which has been determined to include the number of errors eₚ of the first decoding.

As illustrated in FIG. 10, first, the error cancellation unit 262 rotates c_{col} by 90 degrees using the sub-block S_{t,t} detected in step S11 as a reference to calculate a c_{col}^{T} (step S21). Then, the error cancellation unit 262 calculates an EXOR operation result c_{EXOR} by performing an EXOR operation of c_{row} and c_{col}^{T} in bit units (step S22). The EXOR operation result c_{EXOR} includes a sub-block that is S_{t,t} and a result of the EXOR operation of S_{t,t} as illustrated in the second and third stages of FIG. 11 (the third sub-blocks from the left of the second and third stages of FIG. 11). Therefore, values of all bits of the sub-block of c_{EXOR} are zero. Further, from the properties of linear code described above, c_{EXOR} is also a codeword.

Then, the error cancellation unit 262 generates c_{row}_{_{—}}_{EC} and c_{col}_{_{—}}_{EC}^{T} from c_{EXOR} (step S23). To be specific, the error cancellation unit 262 duplicates c_{EXOR} to generate c_{row}_{_{—}}_{EC} and c_{col}_{_{—}}_{EC}^{T}. Then, when c_{EXOR} has an error (Yes in step S24), the error cancellation unit 262 decomposes an error position of c_{EXOR} (a sub-block having an error) into c_{row}_{_{—}}_{EC} and c_{col}_{_{—}}_{EC}^{T} (step S25). Whether c_{EXOR} has an error can be determined based on the reliability information calculated in the first decoding. In the example of FIG. 11, an error is remained in the second sub-block and the seventh sub-block from the left of the third stage. In this case, it is known that the reliability of the second sub-block from the top of c_{col} is low (a possibility that there is an error is high) and the reliability of the seventh sub-block from the left of c_{row} is low based on the reliability information of the first decoding of c_{col} and c_{row}, and thus it is known that the reliability of the second sub-block from the left of c_{col}_{_{—}}_{EC}^{T} and of the seventh sub-block from the left of c_{row}_{_{—}}_{EC} are low. Therefore, the reliability information of the second sub-block from the top of c_{col} is provided as the reliability information of the second sub-block from the left of c_{col}_{_{—}}_{EC}^{T}, and the reliability information of the seventh sub-block from the left of c_{row} is provided as the reliability information of the seventh sub-block from the left of c_{row}_{_{—}}_{EC}. As described above, in the decoding performed after the error cancellation processing, information indicating there is a high possibility that the second sub-block from the left of c_{col}_{_{—}}_{EC}^{T} and the seventh sub-block from the left of c_{row}_{_{—}}_{EC} include an error is passed. Note that, the example of FIG. 11 illustrates an example in which an error exists in the sub-blocks other than the sub-block S_{t,t}, and thus step S24 is “Yes”. However, when an error does not exist in the sub-blocks other than the sub-block S_{t,t}, step 24 becomes “No”, and step 25 is skipped.

Next, the error cancellation unit 262 rotates c_{col}_{_{—}}_{EC}^{T} by −90 degrees to calculate a codeword c_{col}_{_{—}}_{EC} in the column direction (step S26). As described above, a possibility of correcting the eₚ errors remained in c_{EXOR} and e_{q} errors is increased by performing of the first decoding or the second decoding, using the calculated c_{row}_{_{—}}_{EC} and c_{col}_{_{—}}_{EC} instead of c_{row} and c_{col} of the block product code. A possibility of correcting the errors of S_{t,t} is increased by correcting of c_{row} and c_{col} using a correction result when the eₚ errors and the e_{q} errors can be corrected, and then by decoding of c_{row} and c_{col}.

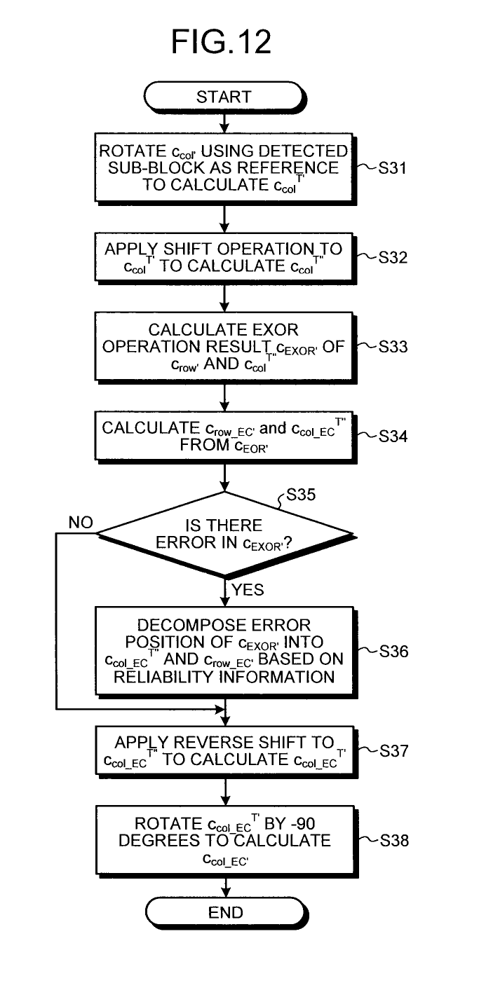

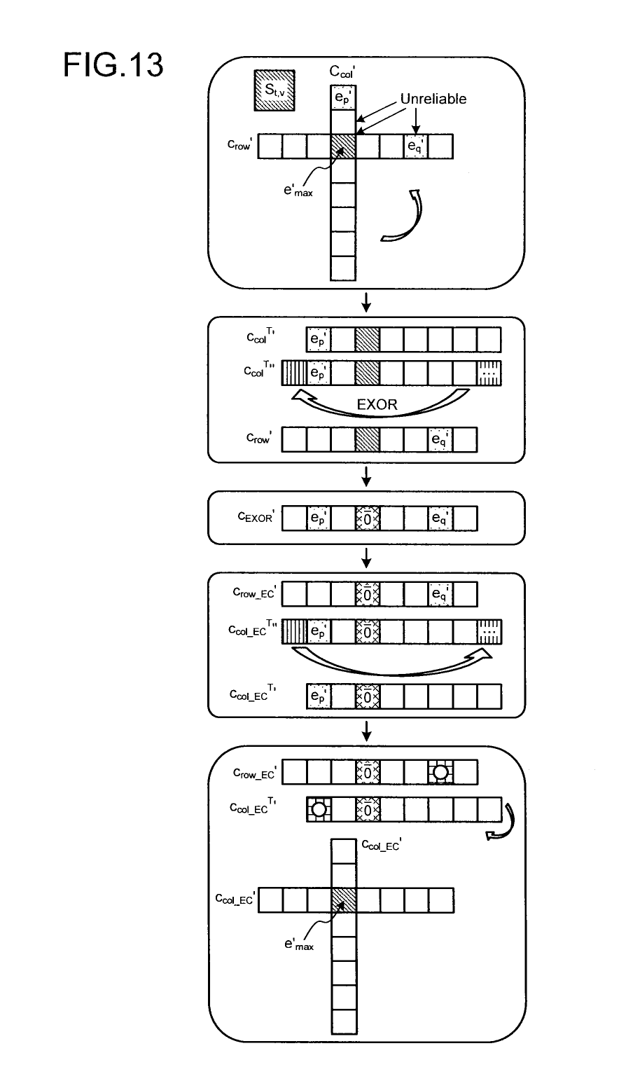

Next, a case of t≠v will be described. FIG. 12 is a diagram illustrating an example of a processing procedure of error cancellation of S_{t,v}. FIG. 13 is a diagram schematically illustrating the error cancellation of S_{t,v}. As illustrated in FIG. 12, similarly to step S21 of the case of S_{t,t}, the error cancellation unit 262 rotates c_{col}^{′} by 90 degrees using the detected sub-block S_{t,v} as a reference to calculate c_{col}^{T′} (step S31).

Next, the error cancellation unit 262 applies a shift operation to c_{col}^{T′} such that the position of the sub-block S_{t,v} becomes equal to the position of S_{t,v} in c_{col}, to calculate c_{col}^{T″} that is c_{col}^{T′} after shifting (step S32). In the case of S_{t,t}, when rotating c_{col} by 90 degrees, the position of S_{t,t} as it is the same position in c_{row} and in c_{col}^{T}. However, in the case of t≠v, the positions of St,v are different in c_{col} and in c_{col}^{T′}, and even if performing the EXOR operation, the error cancellation unit 262 cannot perform the error cancellation like the case of S_{t,t}. Therefore, the error cancellation unit 262 causes the position of S_{t,v} to accord with the position of c_{row} by shifting c_{col}^{T′} by use of the properties of cyclic linear code.

Then, the error cancellation unit 262 calculates an EXOR operation result c_{EXOR}^{′} by performing the EXOR operation of c_{row}^{′} and c_{col}^{T″} in bit units (step S33). The EXOR operation result c_{EXOR}^{′} includes a sub-block that is S_{t,v} and an EXOR of S_{t,v}, as illustrated in the second and third stages of FIG. 13 (the fourth sub-blocks from the left of the second and third stages of FIG. 13). Therefore, values of all bits of the sub-block of c_{EXOR}^{′} are 0. Further, from the properties of cyclic linear code as described above, c_{EXOR}^{′} is also a codeword.

Then, the error cancellation unit 262 generates c_{row}_{_{—}}_{EC}^{′} and c_{col}_{_{—}}_{EC}^{T″} from c_{EXOR}^{′} (step S34). To be specific, the error cancellation unit 262 duplicates c_{EXOR}^{′} to generate c_{row}_{_{—}}_{EC}^{′} and c_{col}_{_{—}}_{EC}^{T″}. Then, when c_{EXOR}^{′} has an error (Yes in step S35), the error cancellation unit 262 decomposes an error position of c_{EXOR}^{′} (a sub-block having an error) into c_{row}_{_{—}}_{EC}^{′} and c_{col}_{_{—}}_{EC}^{T′} (step S36). A decomposing method is similar to the case of S_{t,t}. Next, the error cancellation unit 262 applies a reverse shift operation to c_{col}_{_{—}}_{EC}^{T″} to calculate c_{col}_{_{—}}_{EC}^{T′} (step S37). The reverse shift operation is to perform a shift operation in a reverse direction to the shift operation performed in step S32. Then, the error cancellation unit 262 rotates c_{col}_{_{—}}_{EC}^{T′} by −90 degrees to calculate a codeword c_{col}_{_{—}}_{EC}^{′} in the column direction (step S38). When c_{EXOR}^{′} does not have an error (No in step S35), the processing proceeds to step S38. As described above, in the case of t≠v, the error cancellation can be performed.

As described above, in the present embodiment, a codeword in which errors of a sub-block having the largest number of errors has been cancelled can be obtained by performing of an EXOR operation of codewords in the row direction and in the column direction having a sub-block, which has been determined to have the largest number of errors based on the reliability information obtained in the decoding processing, in decoding of a block product code. Therefore, the possibility of correcting the errors is increased and the error correction capability can be increased by performing of decoding using the codeword from which the errors have been cancelled. Further, the number of errors included in data that serves as an input in the subsequent decoding processing is decreased, and thus the decoding processing can be accelerated.

Note that, while the error cancellation has been applied to the storage device in the above description, an application range of the error cancellation is not limited to the storage device, and can be applied to any device that decodes the block product code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory controller that controls a non-volatile memory capable of storing a block product code including a plurality of row codewords and column codewords, the row codeword being a codeword in a row direction, the column codeword being a codeword in a column direction, and each of the row codewords and the column codewords including a plurality of sub-blocks, the memory controller comprising:
a first decoder configured to decode the block product code, and to calculate reliability information of each sub-block of the row codewords and the column codewords; and
an error cancellation unit configured to detect an error sub-block which has errors based on the reliability information, and to execute exclusive OR for calculating an exor-codeword of a first codeword and a second codeword, the first codeword being the row codeword including the error sub-block, the second codeword being the column codeword including the error sub-block, and
the memory controller performing decoding using the exor-codeword.

2. The memory controller according to claim 1,
wherein, when the detected sub-block is a non-diagonal sub-block that is a sub-block in a position other than a sub-block serving as a diagonal component in the block product code, the error cancellation unit performs a shift operation such that a position of the non-diagonal sub-block in the first codeword is equal to a position of the non-diagonal sub-block in the second codeword, and performs an EXOR operation of the first codeword after the shift operation and the second codeword.

3. The memory controller according to claim 1, further comprising:
an encoder configured to encode user data to be written in the non-volatile memory to generate the block product code.

4. The memory controller according to claim 1,
wherein the codeword is encoded by a cyclic linear code.

5. The memory controller according to claim 1,
wherein the first decoder performs decoding using the exor-codeword.

6. The memory controller according to claim 1,
wherein the first decoder performs decoding by bounded distance decoding.

7. The memory controller according to claim 1, further comprising:
a second decoder configured to perform decoding using the exor-codeword.

8. The memory controller according to claim 7,
wherein the second decoder performs decoding by generalized minimization distance decoding.

9. The memory controller according to claim 7,
wherein the second decoder performs decoding using a decoding method different from the first decoder.

10. The memory controller according to claim 7,
wherein the second decoder performs decoding using a decoding method that is the same as the first decoder.

11. The memory controller according to claim 1,
wherein the exor-codeword is decomposed into a third codeword and a fourth codeword, the third codeword is a codeword in the row direction, and the fourth codeword is a codeword in a column direction, and
the memory controller decodes the third codeword and the fourth codeword.

12. A storage device comprising:
a non-volatile memory capable of storing a block product code including a plurality of row codewords and column codewords, the row codeword being a codeword in a row direction, the column codeword being a codeword in a column direction, and each of the row codewords and the column codewords includes a plurality of sub-blocks;
a first decoder configured to decode the block product code, and to calculate reliability information of each sub-block of the row codewords and the column codewords; and
an error cancellation unit configured to detect an error sub-block which has errors based on the reliability information, and to execute exclusive OR for calculating an exor-codeword of a first codeword and a second codeword, the first codeword being the row codeword including the error sub-block, the second codeword being the column codeword including the error sub-block, and
the storage device performing decoding using the exor-codeword.

13. The storage device according to claim 12,
wherein, when the detected sub-block is a non-diagonal sub-block that is a sub-block in a position other than a sub-block serving as a diagonal component in the block product code, the error cancellation unit performs a shift operation such that a position of the non-diagonal sub-block in the first codeword is equal to a position of the non-diagonal sub-block in the second codeword, and performs an EXOR operation of the first codeword after the shift operation and the second codeword.

14. The storage device according to claim 12, further comprising:
an encoder configured to encode user data to be written in the non-volatile memory to generate the block product code.

15. The storage device according to claim 12,
wherein the codeword is encoded by a cyclic linear code.

16. The storage device according to claim 12,
wherein the first decoder performs decoding using the exor-codeword.

17. The storage device according to claim 12,
wherein the first decoder performs decoding by bounded distance decoding.

18. The storage device according to claim 12, further comprising:
a second decoder configured to perform decoding using the exor-codeword.

19. The storage device according to claim 18,
wherein the second decoder performs decoding by generalized minimization distance decoding.

20. A decoding method of decoding a block product code including a plurality of row codewords and column codewords, the row codeword being a codeword in a row direction, the column codeword being a codeword in a column direction, and each of the row codewords and the column codewords including a plurality of sub-blocks, the method comprising:
decoding the block product code, and calculating reliability information of each sub-block of the row codewords and the column codewords;
detecting an error sub-block which has errors based on the reliability information;
executing exclusive OR for calculating an exor-codeword of a first codeword and a second codeword, the first codeword being the row codeword including the error sub-block, the second codeword being the column codeword including the error sub-block; and
performing decoding using the exor-codeword.
